(19) United States
(12) Patent Application Publication
(10) Pub. No.: US 2013/0316094 A1
(43) Pub. Date: Nov. 28, 2013

(54) RF-POWERED, TEMPERATURE-CONTROLLED GAS DIFFUSER

(71) Applicant: Novellus Systems, Inc., San Jose, CA (US)

(72) Inventors: Karl F. Leeser, San Jose, CA (US); Jeremy Tucker, Portland, OR (US); Ramesh Chandrasekharan, Portland, OR (US)

(73) Assignee: Novellus Systems, Inc., San Jose, CA (US)

(21) Appl. No.: 13/900,627

(22) Filed: May 23, 2013

Related U.S. Application Data
(60) Provisional application No. 61/651,881, filed on May 25, 2012.

(51) Int. Cl. C23C 16/455; F24H 3/00

(52) U.S. Cl. CPC C23C 16/455; F24H 3/002
USPC 427/569; 392/407; 118/715; 118/723 R

(57) ABSTRACT

A gas diffusing device includes a first portion defining a gas supply conduit having a first inlet and a first outlet and including a second inlet, a second outlet and passages connecting the second inlet to the second outlet. The passages receive non-conductive fluid to cool the first portion. A second portion is connected to the first portion, includes a diffuser face with spaced holes and defines a cavity that is in fluid communication with the first outlet of the gas supply conduit and the diffuser face. A heater is in contact with the second portion to heat the second portion.

### CROSS-REFERENCE TO RELATED APPLICATIONS

This application claims the benefit of U.S. Provisional Application No. 61/651,881 filed May 25, 2012. The entire disclosure of the application referenced above is incorporated herein by reference.

### FIELD

The present disclosure relates to gas diffusing devices, and more specifically to radio frequency (RF), temperature-controlled gas diffusing devices.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Gas diffusing devices are typically used to introduce gas into a system in a uniform manner. For example only, a gas diffusing device such as a chandelier showerhead may be used to deliver gas to a processing chamber of a chemical vapor deposition (CVD) system, which is used to deposit film onto a substrate. In some applications, the showerhead may be biased by a radio frequency (RF) power source.

Some gas diffusing devices that are RF powered are not actively temperature-controlled. During deposition and clean process steps, the temperature of the showerhead may fluctuate. These temperature changes tend to negatively affect the quality of the film to be deposited or vary ambient conditions in which the wafers are processed over time.

In some deposition processes such as plasma-enhanced chemical vapor deposition (PECVD), process performance can be sensitive to thermal variations in process environment. Active temperature control is desirable to mitigate thermal fluctuations inherent in deposition processes as well as to achieve precise temperature set-points that yield optimal process results.

Some PEVCD systems use an RF-powered, capacitively-coupled plasma (CCP) circuit that includes a grounded electrode that may be temperature-controlled and a powered electrode that is not. This approach is used due to significant RF interference that both heating and cooling components of an active temperature control system can introduce to the CCP circuit. AC power leads, required to electrically heat the electrode, can also conduct RF power away from the CCP circuit. This can either reduce power received by the plasma or create a short circuit. Additionally, traditional cooling systems use a chilled water supply (CWS) as a heat exchange medium. The water in a standard CWS also conducts RF power from the powered electrode, which either reduces the delivered power to the plasma or creates a short circuit.

### SUMMARY

A gas diffusing device includes a first portion defining a gas supply conduit having a first inlet and a first outlet and including a second inlet, a second outlet and passages connecting the second inlet to the second outlet. The passages receive non-conductive fluid to cool the first portion. A second portion is connected to the first portion, includes a diffuser face with spaced holes and defines a cavity that is in fluid communication with the first outlet of the gas supply conduit and the diffuser face. A heater is in contact with the second portion to heat the second portion.

In other features, a radio frequency (RF) lead is connected to the first portion. The first portion includes a stem portion of a showerhead and the second portion includes a base portion of the showerhead. The heater includes a connecting portion and a heating element portion. The heating element portion is located around a periphery of the base portion. The connecting portion passes through the stem portion and is connected to the heating element portion. The base portion comprises an upper layer, a middle layer, and a lower layer comprising the diffuser face. The heating element is arranged between the upper layer and the middle layer.

In other features, the upper layer and the middle layer of the base portion are vacuum brazed. The first portion defines an outer surface, an inner surface and an inner cavity. The gas supply conduit passes through the inner cavity and the passages are located between the gas supply conduit and the inner surface of the first portion. The first portion includes baffles extending radially from the gas supply conduit to the inner surface to define the passages. The passages define a serpentine path for the non-conductive fluid from the second inlet to the second outlet.

In other features, a conductor passes through the first portion and between the upper layer and the middle layer of the second portion. A thermocouple is connected to the conductor and arranged in the middle layer of the second portion. The thermocouple is located adjacent to a radially outer edge of the middle layer.

A system includes the gas diffusing device and a controller. The controller is configured to control a temperature of the gas diffusing device by supplying current to the heating element in response to a signal from the thermocouple, and supplying process gas to the gas supply conduit and the non-conductive fluid to the inlet.

A substrate processing system comprises a processing chamber, the gas diffusing device and a pedestal arranged adjacent to the diffuser face of the gas diffusing device. The substrate processing system performs plasma-enhanced chemical vapor deposition.

A method for controlling a temperature of a gas diffusing device includes supplying non-conductive fluid to a first portion of the gas diffusing device. The first portion defines a gas supply conduit having a first inlet and a first outlet and includes a second inlet, a second outlet and passages connecting the second inlet to the second outlet to receive the non-conductive fluid. The method further includes supplying current to a heater arranged in a second portion of the gas diffusing device. The second portion is connected to the first portion, includes a diffuser face with spaced holes and defines a cavity that is in fluid communication with the first outlet of the gas supply conduit and the diffuser face.

In other features, the method includes selectively supplying a radio frequency (RF) signal to the first portion. The first portion includes a stem portion of a showerhead and the second portion includes a base portion of the showerhead. The heater includes a connecting portion and a heating element portion. The method further includes arranging the heating element portion around a periphery of the base portion, passing the connecting portion through the stem portion, and connecting the connecting portion to the heating element portion.

In other features, the base portion comprises an upper layer, a middle layer, and a lower layer comprising the diffuser face. The method includes arranging the heating element between the upper layer and the middle layer. The upper layer and the middle layer of the base portion are vacuum brazed. The first portion defines an outer surface, an inner surface and an inner cavity. The gas supply conduit passes through the inner cavity and the passages are located between the gas supply conduit and the inner surface of the first portion.

In other features, the first portion includes baffles extending radially from the gas supply conduit to the inner surface to define the passages. The passages define a serpentine path for the non-conductive fluid from the second inlet to the second outlet.

In other features, the method includes passing a conductor through the first portion and between the upper layer and the middle layer of the second portion; and connecting a thermocouple to the conductor. The method includes locating the thermocouple adjacent to a radially outer edge of the middle layer.

In other features, the method includes using the gas diffusing device in a plasma-enhanced chemical vapor deposition system.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a perspective view of a gas diffusing device according to the present disclosure;

FIG. 2 is a cross-sectional perspective view of a gas diffusing device according to the present disclosure;

FIGS. 3A and 3B are enlarged perspective views illustrating cooling of a gas diffusing device according to the present disclosure;

FIGS. 4A-4C are enlarged perspective views illustrating cooling of a gas diffusing device according to the present disclosure;

FIGS. 5-6 are perspective views illustrating an RF power conductor of a gas diffusing device according to the present disclosure;

FIG. 7 is a cross-sectional perspective view illustrating a temperature thermocouple of a gas diffusing device according to the present disclosure;

FIG. 8 is a functional block diagram of an example of a PECVD processing chamber; and

FIG. 9 is a functional block diagram of an example of a controller for controlling the PECVD processing chamber.

### DETAILED DESCRIPTION

The present disclosure relates to temperature-controlled gas diffusing devices. In some examples, the gas diffusing devices are also biased by an RF signal to operate as an RF powered electrode in a capacitively-coupled plasma source. The gas diffusing device is actively heated with an internal heating element and cooled using non-conductive fluid such as a non-conductive gas to achieve and maintain a desired operating temperature.

As a result, a diffuser face of the gas diffusing device remains at a specified temperature set point despite fluctuating inputs from the environment. In some examples, the gas diffusing device includes a showerhead that is a powered electrode in a capacitively-coupled plasma circuit used in a PECVD process chamber. While a PECVD process is disclosed herein, the gas diffusing device can be used for other film processes such as plasma-enhanced atomic layer deposition (PEALD), conformal film deposition (CFD), and/or other processes.

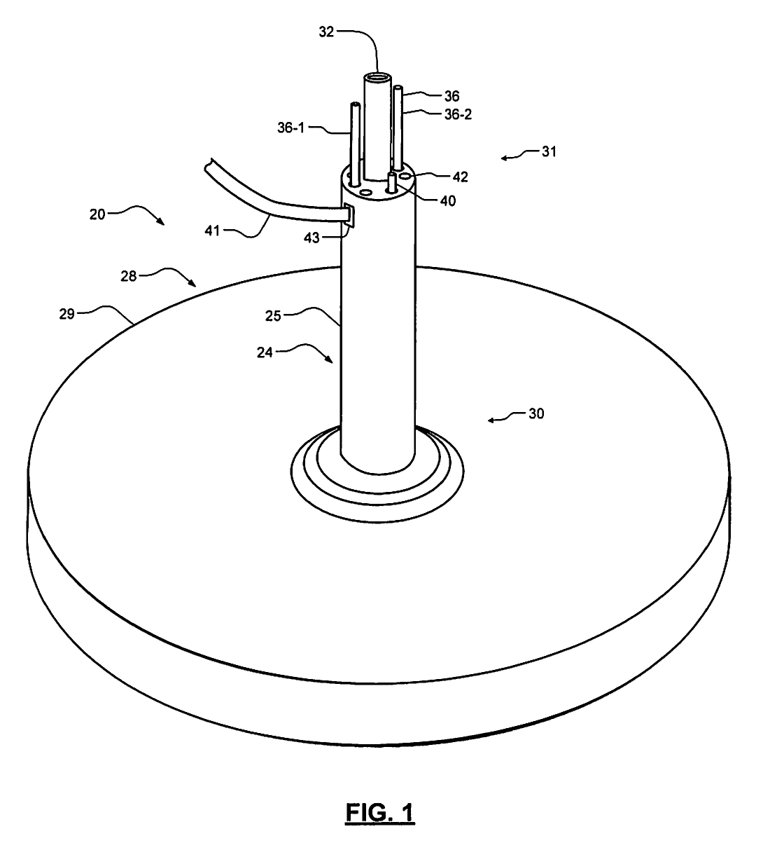

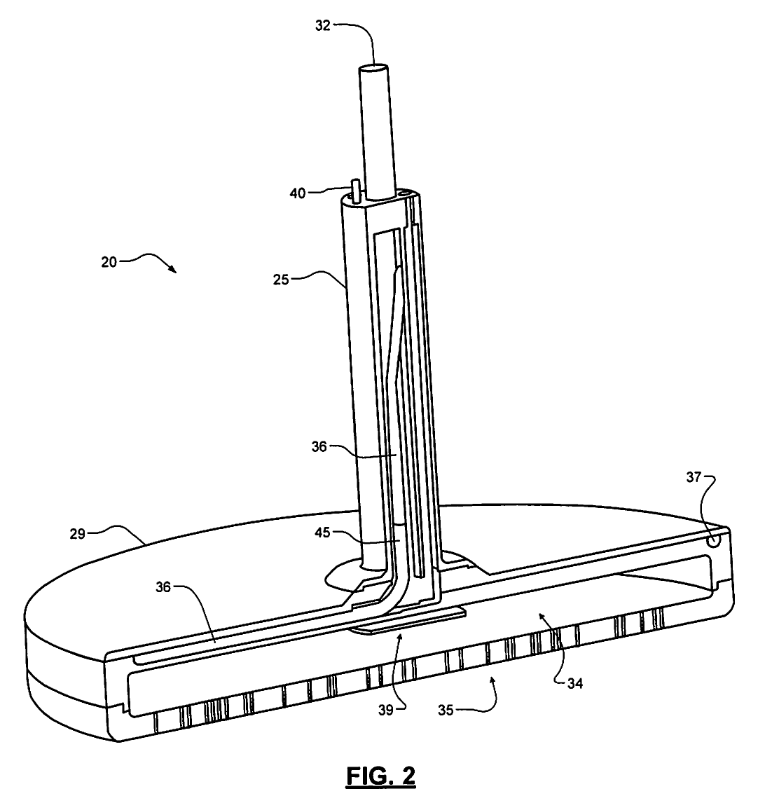

Referring now to FIGS. 1 and 2, an example of a gas diffusing device according to the present disclosure is shown. In FIG. 1, the gas diffusing device includes a showerhead 20 including a first portion 24 and a second portion 28. When the gas diffusing device is a showerhead, the first portion 24 may correspond to a stem portion 25 and the second portion 28 may correspond to a base portion 29. While the foregoing description will be made in the context of a showerhead, other gas diffusing devices are contemplated.

The stem portion 25 includes a lower end 30 that is connected to the base portion 29 and an upper end 31 connected to a wall of a processing chamber. In some examples, a lead 41 supplying a radio frequency (RF) bias is attached directly to the stem portion 25 or attached to the stem portion 25 using a fastener 43 such as a clamping device. Alternately, the RF bias may be supplied to a pedestal and the lead 41 may be a ground lead.

A gas supply conduit 32 passes through the stem portion 25 to supply gas to a cavity 34 (FIG. 2) of the showerhead 20. Gas flows from the cavity 34 of the showerhead 20 through a diffuser face 35 (FIG. 2) and into a processing chamber. A heater includes heater electrodes 36 with first and second ends 36-1 and 36-2. The heater electrodes 36-1 are routed through the stem portion 25 and connected to a resistance heating element 37 in the base portion 29. The resistance heating element 37 circumscribes a periphery of the base portion 29 and is connected back to the heater electrode 36-2. Portions of the heater electrodes 36 can be enclosed in a metal sheath 41.

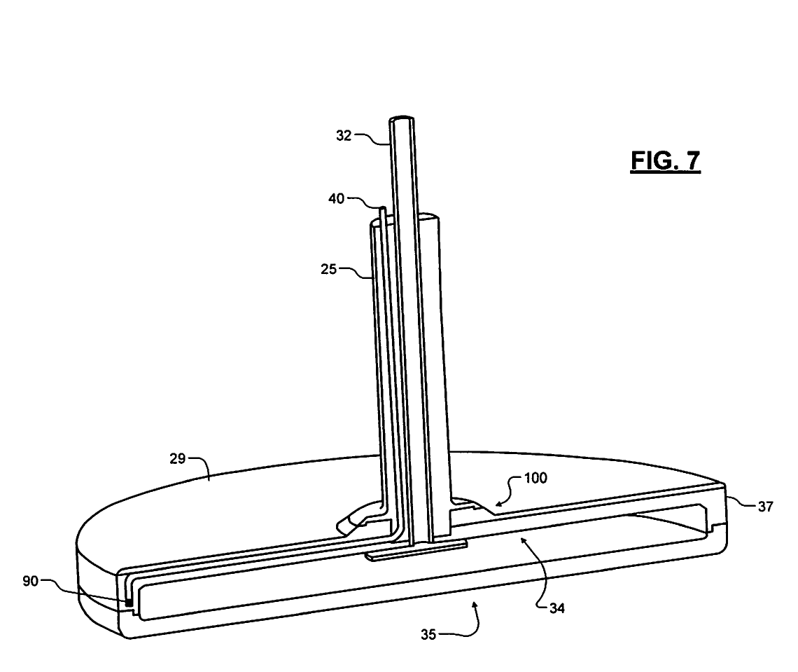

A platen 39 may be used to disburse the process gas exiting the gas supply conduit 32 as the gas enters the cavity 34. A conductor 40 is connected to a thermocouple (FIG. 7). The conductor 40 is routed through the stem portion 25 and into the base portion 29 to connect to the thermocouple to provide temperature feedback. In some examples, first and second thermocouples are used for redundancy. One or more threaded inserts 42 or other attachment devices may be provided to position the showerhead 20 relative to the processing chamber.

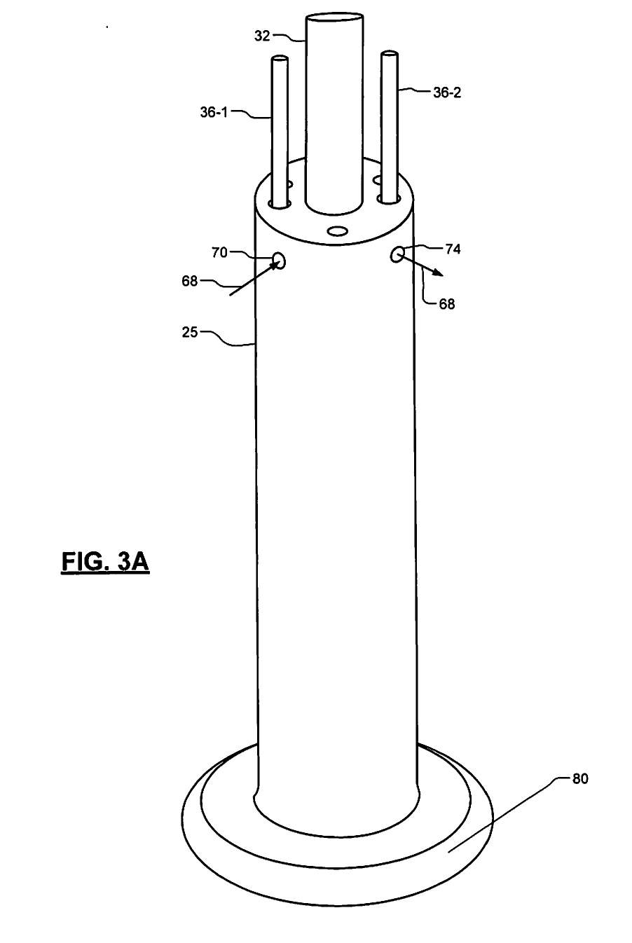

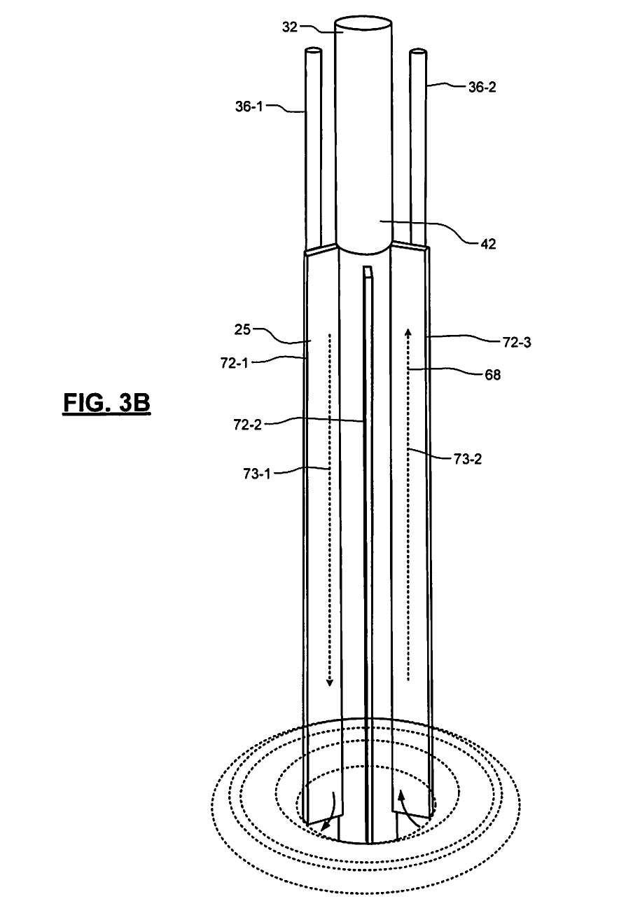

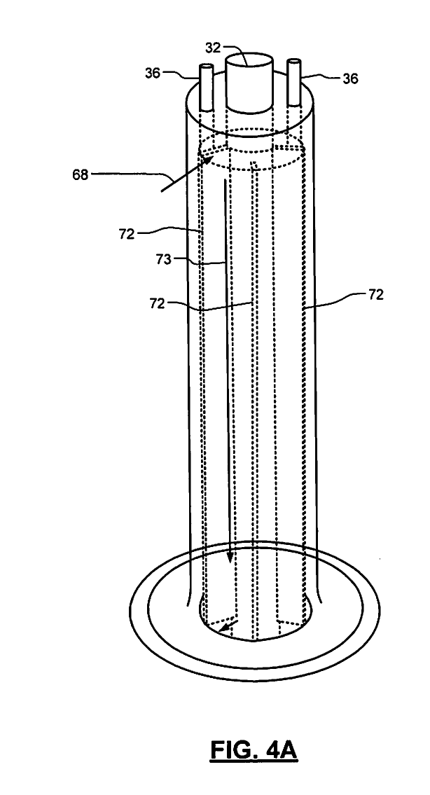

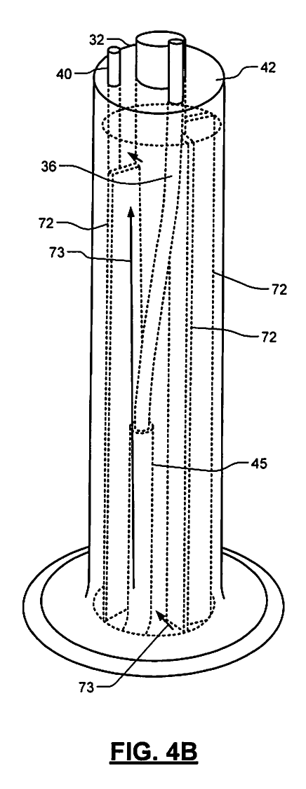

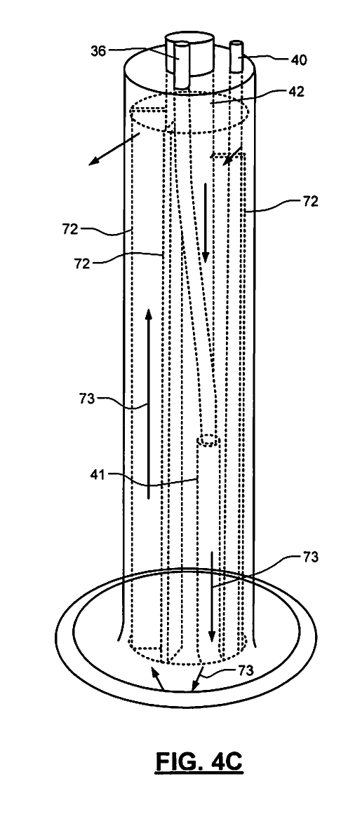

Referring now to FIGS. 3A-4C, the showerhead includes a cooler that uses non-conductive fluid such as a non-conductive gas as a heat exchange medium for cooling. A cavity in the stem portion 25 of the showerhead acts as a heat exchanger. Cooling gas 68 enters the stem portion 25 at an inlet port 70 and is directed by baffles 72 that define two or more passages 73. The passages 73 define a serpentine path for the gas up, down and around the stem portion 25 and connect to an outlet port 74. The cooler is electrically isolated from the heater electrode 36 and does not conduct RF power away from the plasma circuit.

In FIG. 3A, gas is shown entering the inlet port 70 and exiting the outlet port 74. In FIG. 3B, gas is shown traveling down one passage 73-1 (between baffles 72-1 and 72-2) and back up an adjacent passage 73-2 (between baffles 72-2 and 72-3). FIGS. 4A-4C show additional views of the baffles 72 and passages 73. The heater electrodes 36 and the conductor 40 pass through one or more of the passages 73.

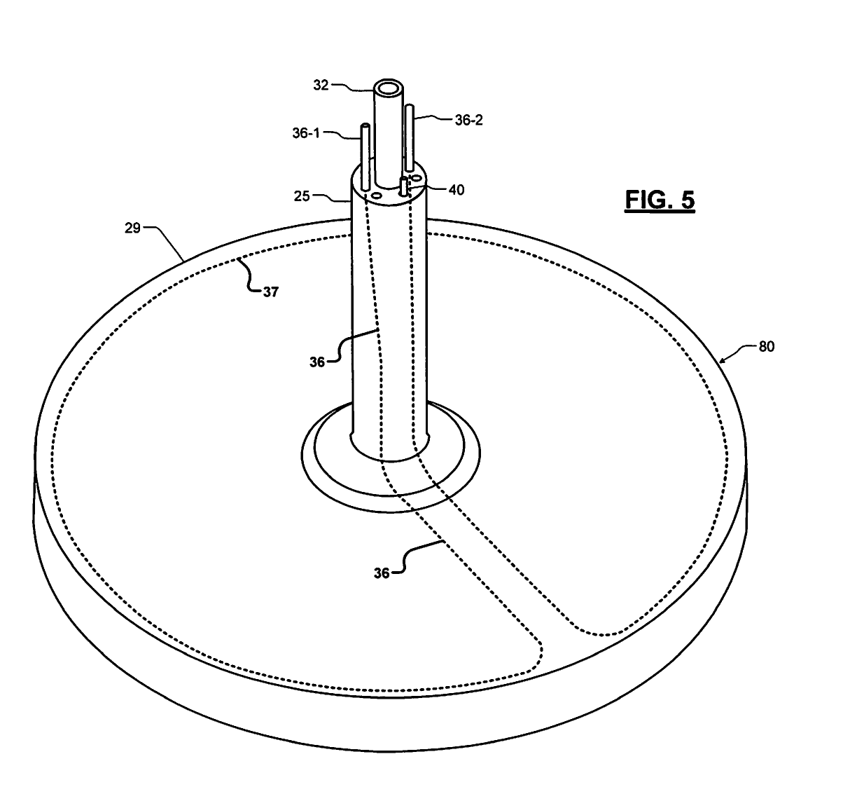

In FIGS. 5-7, the showerhead 20 is heated by the resistance heating element 37, which is connected to the heater electrodes 36. In FIG. 5, the heater electrodes 36 are shown passing through the stem portion 25. The heater electrodes 36 extend radially outwardly to a periphery of the base portion 29 and connect to the resistance heater element 37.

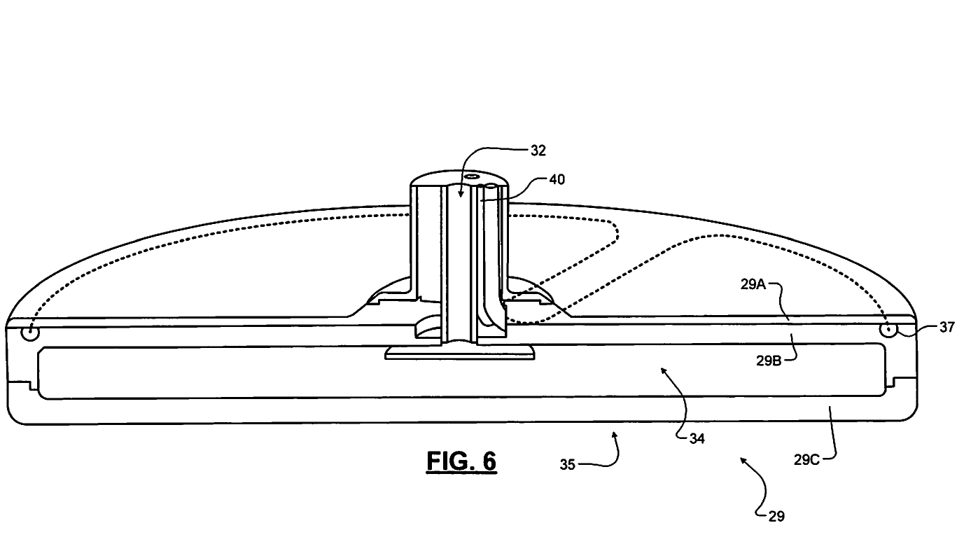

In FIG. 6, an example of the base portion 29 includes an upper layer 29A, a middle layer 29B and a lower layer 29C including the diffuser face 35. The resistance heating element 37 is brazed into an outer edge 80 of the base portion 29 of the showerhead 20. In some examples, the resistance heating element is vacuum brazed between the upper layer 29A and the middle layer 29B of the base portion 29, although other approaches may be used.

The resistance heating element 37 is preferably arranged close to a face where the plasma power enters the assembly and far from the thermal break. The resistance heating element 37 may be placed in close proximity to the diffuser face 35 of the showerhead 20 as this region is directly involved in the deposition process. Temporal variation in temperature is reduced, which allows higher quality film to be deposited.

In FIG. 7, the conductor 40 and one or more thermocouples 90 are used to monitor and control the temperature of the base portion 29. In some examples, the thermocouple 90 is located closer to the diffuser face 35 than the resistance heating element 37. As a result, the resistance heating element 37 and a measurement location of the one or more thermocouples 90 are largely collocated.

A region 100 of the stem portion 25 including a thin-walled tube (gas supply conduit 32) acts as a thermal break, which provides some separation between a region being heated and a region being cooled. This separation minimizes the degree to which the heating and cooling systems compete with each other. Gas heat exchange in the stem portion 25 acts as thermal ballast, which allows the showerhead 20 to rapidly cool whenever the heat load is reduced. This keeps the stem portion 25 of the showerhead 20, which extends out of the process chamber and can be touched, at a cooler temperature and provides a somewhat constant temperature reference for the showerhead 20.

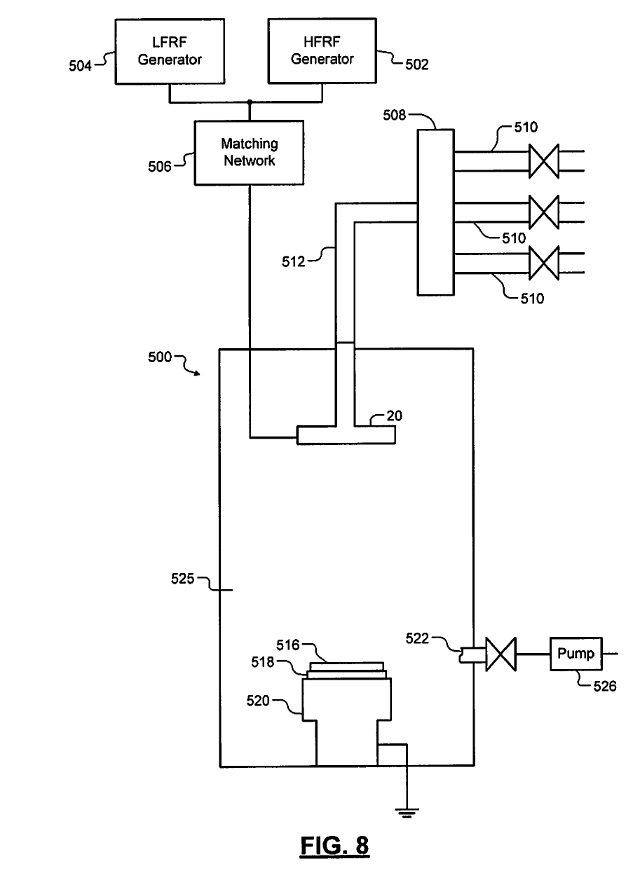

The showerhead 20 may be used for example in a reactor 500 in FIG. 8. The reactor 500 includes a process chamber 524, which encloses other components of the reactor 500 and contains the plasma. The plasma may be generated by a capacitor type system including the showerhead 20 connected to the RF lead 45 and a grounded heater block 520. A high-frequency RF generator 502 and a low-frequency RF generator 504 are connected to a matching network 506 and to the showerhead 514. The power and frequency supplied by matching network 506 is sufficient to generate plasma from the process gas.

Within the reactor, a pedestal 518 supports a substrate 516. The pedestal 518 typically includes a chuck, a fork, or lift pins to hold and transfer the substrate during and between the deposition and/or plasma treatment reactions. The chuck may be an electrostatic chuck, a mechanical chuck or other type of chuck.

The process gases are introduced via inlet 512. Multiple source gas lines 510 are connected to a manifold 508. The gases may be premixed or not. Appropriate valving and mass flow control mechanisms are employed to ensure that the correct gases are delivered during the deposition and plasma treatment phases of the process.

Process gases exit chamber 524 via an outlet 522. A vacuum pump 526 (e.g., a one or two stage mechanical dry pump and/or a turbomolecular pump) draws process gases out and maintains a suitably low pressure within the reactor by a close loop controlled flow restriction device, such as a throttle valve or a pendulum valve.

It is possible to index the wafers after every deposition and/or post-deposition plasma anneal treatment until all the required depositions and treatments are completed, or multiple depositions and treatments can be conducted at a single station before indexing the wafer.

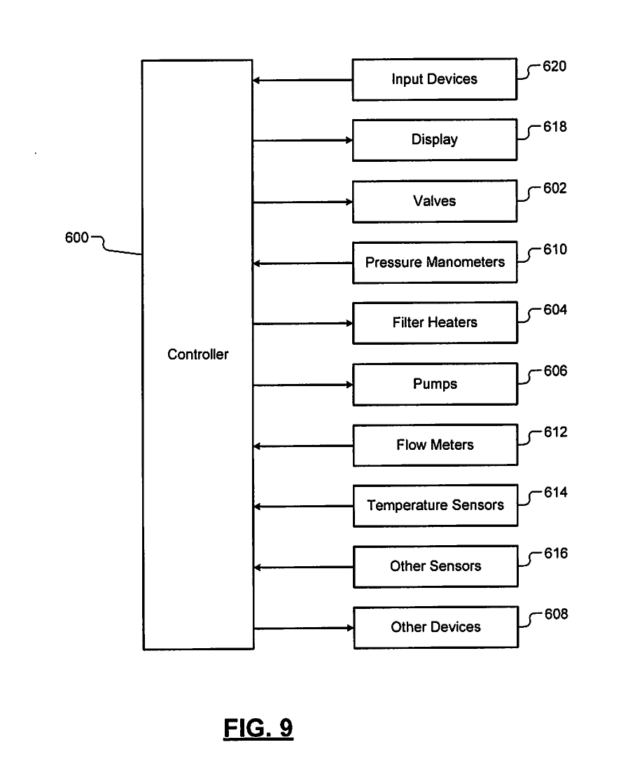

Referring now to FIG. 9, a controller 600 for controlling the system of FIG. 8 is shown. The controller 600 may include a processor, memory and one or more interfaces. The controller 600 may be employed to control devices in the system base portioned in part on sensed values. In addition, the controller 600 may be used to control heating and cooling of the showerhead 20. In particular, the controller 600 may be used to control the flow of gas to the cooling system and/or power supplied to the resistance heating element 37 base portioned on feedback from the thermocouple 90.

For example only, the controller 600 may control one or more of valves 602, filter heaters 604, pumps 606, and other devices 608 base portioned on the sensed values and other control parameters. The controller 600 receives the sensed values from, for example only, pressure manometers 610, flow meters 612, temperature sensors 614, and/or other sensors 616. The controller 600 may also be employed to control process conditions during precursor delivery and deposition of the film. The controller 600 will typically include one or more memory devices and one or more processors.

The controller 600 may control activities of the precursor delivery system and deposition apparatus. The controller 600 executes computer programs including sets of instructions for controlling process timing, delivery system temperature, pressure differentials across the filters, valve positions, mixture of gases, chamber pressure, chamber temperature, wafer temperature, RF power levels, wafer chuck or pedestal position, and other parameters of a particular process. The controller 600 may also monitor the pressure differential and automatically switch vapor precursor delivery from one or more paths to one or more other paths. Other computer programs stored on memory devices associated with the controller 600 may be employed in some embodiments.

Typically there will be a user interface associated with the controller 600. The user interface may include a display 618 (e.g. a display screen and/or graphical software displays of the apparatus and/or process conditions), and user input devices 620 such as pointing devices, keyboards, touch screens, microphones, etc.

The controller parameters relate to process conditions such as, for example, filter pressure differentials, process gas composition and flow rates, temperature, pressure, plasma conditions such as RF power levels and the low frequency RF frequency, cooling gas pressure, and chamber wall temperature.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A filter monitoring program includes code comparing the measured differential(s) to predetermined value(s) and/or code for switching paths. A pressure control program may include code for controlling the pressure in the chamber by regulating, e.g., a throttle valve in the exhaust system of the chamber. A heater control program may include code for controlling the current to heating units for heating components in the precursor delivery system, the substrate and/or other portions of the system. Alternatively, the heater control program may control delivery of a heat transfer gas such as helium to the wafer chuck.

Examples of sensors that may be monitored during deposition include, but are not limited to, mass flow controllers, pressure sensors such as the pressure manometers 610, and thermocouples located in delivery system such as thermocouple 90, the pedestal or chuck (e.g. the temperature sensors 614). Appropriately programmed feedback and control algorithms may be used with data from these sensors to maintain desired process conditions. The foregoing describes implementation of embodiments of the invention in a single or multi-chamber semiconductor processing tool.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. For purposes of clarity, the same reference numbers will be used in the drawings to identify similar elements. As used herein, the phrase at least one of A, B, and C should be construed to mean a logical (A or B or C), using a non-exclusive logical OR. It should be understood that one or more steps within a method may be executed in different order (or concurrently) without altering the principles of the present disclosure.

As used herein, the term controller may refer to, be part of, or include an Application Specific Integrated Circuit (ASIC); an electronic circuit; a combinational logic circuit; a field programmable gate array (FPGA); a processor (shared, dedicated, or group) that executes code; other suitable hardware components that provide the described functionality; or a combination of some or all of the above, such as in a system-on-chip. The term controller may include memory (shared, dedicated, or group) that stores code executed by the processor.

The term code, as used above, may include software, firmware, and/or microcode, and may refer to programs, routines, functions, classes, and/or objects. The term shared, as used above, means that some or all code from multiple controllers may be executed using a single (shared) processor. In addition, some or all code from multiple controllers may be stored by a single (shared) memory. The term group, as used above, means that some or all code from a single controller may be executed using a group of processors. In addition, some or all code from a single controller may be stored using a group of memories.

What is claimed is:

1. A gas diffusing device, comprising:
a first portion defining a gas supply conduit having a first inlet and a first outlet and including a second inlet, a second outlet and passages connecting the second inlet to the second outlet, wherein the passages receive non-conductive fluid to cool the first portion;
a second portion connected to the first portion, including a diffuser face with spaced holes and defining a cavity that is in fluid communication with the first outlet of the gas supply conduit and the diffuser face; and
a heater in contact with the second portion to heat the second portion.

2. The gas diffusing device of claim 1, further comprising a radio frequency (RF) lead connected to the first portion.

3. The gas diffusing device of claim 1, wherein the first portion includes a stem portion of a showerhead and the second portion includes a base portion of the showerhead.

4. The gas diffusing device of claim 3, wherein the heater includes a connecting portion and a heating element portion, wherein the heating element portion is located around a periphery of the base portion, and wherein the connecting portion passes through the stem portion and is connected to the heating element portion.

5. The gas diffusing device of claim 4, wherein the base portion comprises:
an upper layer;
a middle layer; and
a lower layer comprising the diffuser face,
wherein the heating element is arranged between the upper layer and the middle layer.

6. The gas diffusing device of claim 5, wherein the upper layer and the middle layer of the base portion are vacuum brazed.

7. The gas diffusing device of claim 1, wherein:
the first portion defines an outer surface, an inner surface and an inner cavity, and
the gas supply conduit passes through the inner cavity and the passages are located between the gas supply conduit and the inner surface of the first portion.

8. The gas diffusing device of claim 7, wherein the first portion includes baffles extending radially from the gas supply conduit to the inner surface to define the passages.

9. The gas diffusing device of claim 7, wherein the passages define a serpentine path for the non-conductive fluid from the second inlet to the second outlet.

10. The gas diffusing device of claim 5, further comprising:
a conductor passing through the first portion and between the upper layer and the middle layer of the second portion; and
a thermocouple connected to the conductor and arranged in the middle layer of the second portion.

11. The gas diffusing device of claim 10, wherein the thermocouple is located adjacent to a radially outer edge of the middle layer.

12. A system comprising:
the gas diffusing device of claim 10; and
a controller configured to control a temperature of the gas diffusing device by:
supplying current to the heating element in response to a signal from the thermocouple; and
supplying process gas to the gas supply conduit and the non-conductive fluid to the inlet.

13. A substrate processing system comprising:
a processing chamber;
the gas diffusing device of claim 3; and
a pedestal arranged adjacent to the diffuser face of the gas diffusing device.

14. The substrate processing system of claim 13, wherein the substrate processing system performs plasma-enhanced chemical vapor deposition.

15. A method for controlling a temperature of a gas diffusing device, comprising:
supplying non-conductive fluid to a first portion of the gas diffusing device,
wherein the first portion defines a gas supply conduit having a first inlet and a first outlet and includes a second inlet, a second outlet and passages connecting the second inlet to the second outlet to receive the non-conductive fluid; and
supplying current to a heater arranged in a second portion of the gas diffusing device,
wherein the second portion is connected to the first portion, includes a diffuser face with spaced holes and defines a cavity that is in fluid communication with the first outlet of the gas supply conduit and the diffuser face.

16. The method of claim 15, further comprising selectively supplying a radio frequency (RF) signal to the first portion.

17. The method of claim 15, wherein the first portion includes a stem portion of a showerhead and the second portion includes a base portion of the showerhead.

18. The method of claim 17, wherein the heater includes a connecting portion and a heating element portion, and further comprising
arranging the heating element portion around a periphery of the base portion;
passing the connecting portion through the stem portion; and
connecting the connecting portion to the heating element portion.

19. The method of claim 17, wherein the base portion comprises an upper layer, a middle layer, and a lower layer comprising the diffuser face, and further comprising arranging the heating element between the upper layer and the middle layer.

20. The method of claim 19, wherein the upper layer and the middle layer of the base portion are vacuum brazed.

21. The method of claim 15, wherein:
the first portion defines an outer surface, an inner surface and an inner cavity, and
the gas supply conduit passes through the inner cavity and the passages are located between the gas supply conduit and the inner surface of the first portion.

22. The method of claim 21, wherein the first portion includes baffles extending radially from the gas supply conduit to the inner surface to define the passages.

23. The method of claim 21, wherein the passages define a serpentine path for the non-conductive fluid from the second inlet to the second outlet.

24. The method of claim 19, further comprising:
passing a conductor through the first portion and between the upper layer and the middle layer of the second portion; and
connecting a thermocouple to the conductor.

25. The method of claim 24, further comprising locating the thermocouple adjacent to a radially outer edge of the middle layer.

26. The method of claim 15, further comprising using the gas diffusing device in a plasma-enhanced chemical vapor deposition system.
